(19) United States
(12) Patent Application Publication
(10) Pub. No.: US 2026/0068327 A1
(43) Pub. Date: Mar. 5, 2026

(54) SEMICONDUCTOR DEVICE

(71) Applicant: Sanken Electric Co., Ltd., Saitama-ken (JP)

(72) Inventor: Naoto Fujita, Saitama-ken (JP)

(73) Assignee: Sanken Electric Co., Ltd., Saitama-ken (JP)

(21) Appl. No.: 19/290,368

(22) Filed: Aug. 5, 2025

(30) Foreign Application Priority Data
Sep. 2, 2024 (JP) 2024-150490

(51) Int. Cl. H10D 89/60; H10D 8/00; H10D 10/60; H10D 30/65; H10D 62/10; H10D 64/00; H10D 64/27; H10D 84/00

(52) U.S. Cl. CPC H10D 89/711; H10D 8/411; H10D 10/60; H10D 30/655; H10D 62/107; H10D 62/126; H10D 64/112; H10D 64/518; H10D 84/151; H10D 84/153; H10D 89/611; H10D 89/811

(57) ABSTRACT

The semiconductor device includes an n-type first semiconductor region 11 formed on a surface side of a p-type semiconductor substrate 10 and serving as a common path for currents flowing through a switching element and a protection element, an n-type common contact region 12 formed on the first semiconductor region 11 with a high impurity concentration and connected to a common electrode 21 serving as both a first main electrode and a protection element side first electrode, a p-type second semiconductor region 13 and a p-type third semiconductor region 14 locally formed in the first semiconductor region 11 at locations separated from the common contact region 12, and an n-type fourth semiconductor region 15 locally formed in the second semiconductor region 13 in plan view. A second main electrode 22 is connected to the fourth semiconductor region 15, and a protection element side second electrode 26 is provided inside the third semiconductor region 14.

### CROSS-REFERENCE TO RELATED APPLICATION

This application claims the priority benefit of Japanese application serial no. 2024-150490, filed on Sep. 2, 2024. The entirety of the above-mentioned patent application is hereby incorporated by reference herein and made a part of this specification.

### TECHNICAL FIELD

The disclosure relates to a semiconductor device in which a lateral switching element and a protection element thereof are combined.

### BACKGROUND

As a power semiconductor element, a lateral LDMOS (laterally diffused MOS) transistor having a drift layer, through which an on current flows, in the plane direction of a semiconductor layer is preferably used as a switching element to achieve a high breakdown voltage. In this case, the length along the electric field direction of a region (high breakdown voltage region) where the electric field strength becomes particularly high during the off state and therefore the breakdown voltage should be secured is set in the in-plane direction of the semiconductor layer so as to secure the breakdown voltage.

Furthermore, as described in Patent Document 1 (Japanese Patent Application Laid-Open No. 2006-319072), for example, a technique is used in this LDMOS in which a protection element (for example, a diode) is connected between the source and drain of the LDMOS, and in the case where a surge voltage exceeding the breakdown voltage is applied to the LDMOS, this protection element breaks down instead of the LDMOS to bypass the current, thereby preventing damage to the LDMOS and the electric circuits connected thereto.

In this case, the breakdown voltage of this protection element (diode) is set high corresponding to the LDMOS. Therefore, this diode is also lateral, and the high breakdown voltage region is set with a certain size in the diode as well, similar to the LDMOS. In the technique described in Patent Document 1, the LDMOS is formed in one region on a plane, and the region constituting the diode is formed surrounding this LDMOS.

As described above, in order to form both the LDMOS and the lateral protection element on a common semiconductor substrate and to increase the breakdown voltage of both, a large area is required for the total region occupied by both. Alternatively, in the case of a limited area, the current capacity flowing through the LDMOS or the protection element can not be increased, resulting in a reduction in the protection function. Therefore, it has been difficult to obtain a compact semiconductor device with a high breakdown voltage in which a switching element and a protection element that protects the switching element are combined.

The disclosure provides a semiconductor device that solves the above problems.

### SUMMARY

The disclosure has the following configuration to solve the above problems.

The semiconductor device of the disclosure is a semiconductor device, in which a switching element whose on/off is controlled between a first main electrode on a high potential side and a second main electrode on a low potential side, and a protection element that bypasses and flows a current between a protection element side first electrode on the high potential side and a protection element side second electrode on the low potential side during an off state of the switching element are formed on a semiconductor substrate. The semiconductor device includes: a first semiconductor region of a second conductivity type formed on a surface side of the semiconductor substrate of a first conductivity type, in which the second conductivity type is opposite to the first conductivity type; a common electrode serving as both the first main electrode and the protection element side first electrode; a common contact region of the second conductivity type formed locally with a high impurity concentration on the first semiconductor region and connected to the common electrode; a second semiconductor region of the first conductivity type locally formed in the first semiconductor region separated from the common contact region in plan view; a third semiconductor region of the first conductivity type separated from the common contact region and the second semiconductor region and locally formed in the first semiconductor region in plan view; and a fourth semiconductor region of the second conductivity type locally formed in the second semiconductor region in plan view. One of the second semiconductor region and the third semiconductor region is formed to surround the other of the second semiconductor region and the third semiconductor region on an outer side as viewed from the common contact region. The fourth semiconductor region and the second main electrode are connected, and the third semiconductor region and the protection element side second electrode are connected.

A fifth semiconductor region of the second conductivity type may be provided in the third semiconductor region in plan view, and the protection element side second electrode may be connected to the fifth semiconductor region and the third semiconductor region.

The second semiconductor region may be formed in an annular shape surrounding the common contact region in plan view.

The other of the second semiconductor region and the third semiconductor region may be the third semiconductor region.

The third semiconductor region may be divided and provided as a plurality of regions in plan view.

The other of the second semiconductor region and the third semiconductor region may be the third semiconductor region, and the first semiconductor region may be formed deeper below the third semiconductor region than an inner side of the third semiconductor region in plan view.

The semiconductor device may include a first control electrode controlling on/off between the first main electrode and the second main electrode in the switching element, and formed on the second semiconductor region; and a second control electrode connected to the second semiconductor region.

The semiconductor device may include an inter-element field plate electrically connected to any of the first control electrode, the second control electrode, and the third semiconductor region, and facing a surface of the first semiconductor region between the second semiconductor region and the third semiconductor region in plan view through an insulating layer.

The one of the second semiconductor region and the third semiconductor region may be the third semiconductor region.

The first semiconductor region may not be formed outside the one of the second semiconductor region and the third semiconductor region.

Since the disclosure is configured as described above, it is possible to obtain a compact semiconductor device with a high breakdown voltage in which a switching element and a protection element that protects the switching element are combined.

### BRIEF DESCRIPTION OF THE DRAWINGS

FIG. 1 is a circuit diagram showing the configuration of the semiconductor device according to an embodiment of the disclosure.

FIG. 2 is a cross-sectional view showing the configuration of the semiconductor device according to an embodiment of the disclosure.

FIG. 3 is a top view showing the configuration of the semiconductor device according to an embodiment of the disclosure.

FIG. 4 is a cross-sectional view showing the configuration of the first modification example of the semiconductor device according to an embodiment of the disclosure.

FIG. 5 is a cross-sectional view showing the configuration of the second modification example of the semiconductor device according to an embodiment of the disclosure.

FIG. 6 is a cross-sectional view showing the configuration of the third modification example of the semiconductor device according to an embodiment of the disclosure.

FIG. 7 is a top view showing the configuration of the fourth modification example of the semiconductor device according to an embodiment of the disclosure.

FIG. 8 is a top view showing the configuration of the fifth modification example of the semiconductor device according to an embodiment of the disclosure.

FIG. 9 is a circuit diagram showing the configuration of the sixth modification example of the semiconductor device according to an embodiment of the disclosure.

FIG. 10 is a circuit diagram showing the configuration of the seventh modification example of the semiconductor device according to an embodiment of the disclosure.

### DESCRIPTION OF THE EMBODIMENTS

Hereinafter, a semiconductor device according to an embodiment of the disclosure will be described. In the following description of the figures, identical or similar parts are denoted by identical or similar reference numerals. However, it should be noted that the figures are schematic, and the relationship between thickness and planar dimensions, the ratio of length of each part, etc., may differ from actual ones. Therefore, specific dimensions should be determined with reference to the following description. Also, it is needless to say that portions having different dimensional relationships and ratios are included between the figures. Further, the embodiments shown below exemplify devices for embodying the technical concept of the disclosure, and the technical concept of the disclosure does not specify the shape, structure, arrangement, etc. of the components to those described below. The embodiments of the disclosure can be modified in various ways within the scope of the claims. In the disclosure, terms specifying up and down such as “upper” and “lower” are used to facilitate the description, and components that are substantially identical to the components of the disclosure belong to the scope of rights of the disclosure even if they are provided on a side surface. In addition, “on” includes not only the case where an object is formed in contact with another object, but also the case where there is a layer therebetween. Further, in the disclosure, “connection” is not limited to direct connection, and components that are substantially identical to the components of the disclosure belong to the scope of rights of the disclosure even if they are connected with a resistor or the like therebetween.

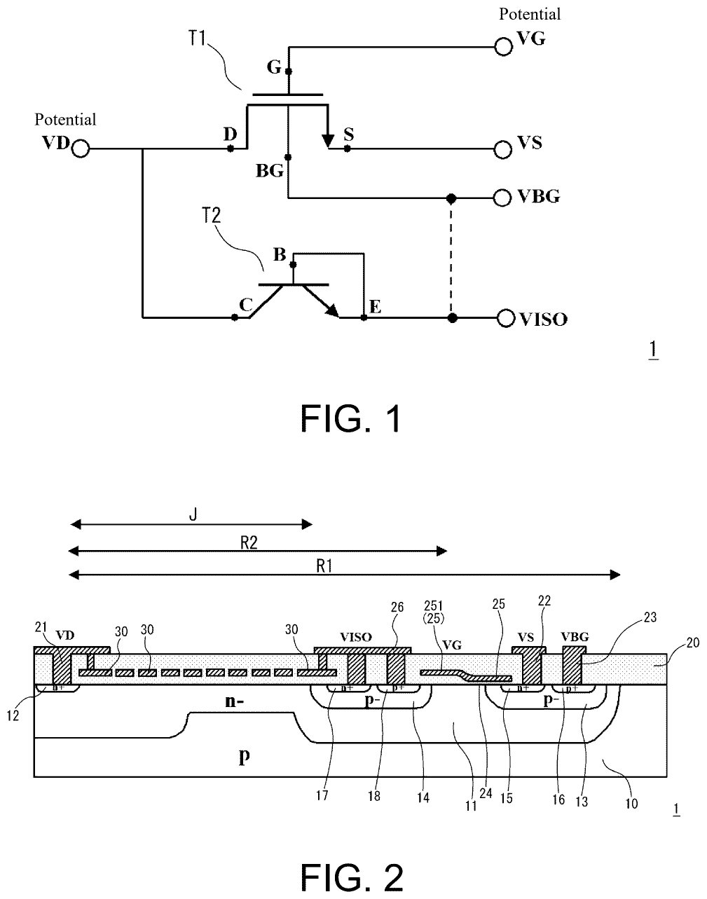

FIG. 1 is a circuit diagram showing the configuration of this semiconductor device 1. Here, an element (switching element) T1 which is an n-channel type MOSFET (LDMOS) as a switching element, and an element (protection element) T2 which is an npn-type bipolar transistor are formed on a common semiconductor substrate. Here, an n-type layer (drift layer) connected to a drain (D: high potential side electrode (first main electrode)) in the element T1 and a collector layer (n-type layer) connected to a collector (C) in the element T2 are common. A source (S: low potential side electrode (second main electrode)), a gate (G: first control electrode), and structures related to these are the same as those of a normal MOSFET, and a potential VS of the source(S) is normally a ground potential (GND), and in the case where a potential VD of the drain (D) is a positive potential, on/off of the current between the drain (D) and the source(S) is controlled by a potential VG of the gate (G).

At this time, a potential VBG of a body layer (BG) of the element T1 (MOSFET) may be set equal to VS, but may also be controlled independently of VS by applying a predetermined potential to a back gate electrode (second control electrode). This makes it possible to adjust the characteristics of the element T1.

In addition, the element T2 is an npn-type bipolar transistor (npn transistor), and the collector (C: protection element side first electrode) thereof is connected to the drain (D) of the element T1, so the aforementioned VD is applied. Also, the potential of an emitter (E: protection element side second electrode) thereof is set to a potential VISO of the outer peripheral portion of the element which is close to ground potential, similar to VBG. However, since the p-type layer serving as the base (B) and the n-type layer serving as the emitter (E) are actually short-circuited by wiring, the element T2 actually operates with two terminals. With the potential settings of VD and VISO as described above, the element T2 is normally in the off state, but in the case where VD becomes large, the element T2 turns on, and can cause a large current to flow. This operation is similar to breakdown in parasitic transistor operation. The characteristics such as the on voltage of the element T2 can be finely adjusted by the spacing between the n⁺ layer 17 and the n⁻ layer 11, the impurity concentration of the p layer 14 and the n layer 11, VISO, etc., which will be described later.

In the case where a positive voltage such as a high voltage surge is applied to the drain (D) side during the off state of the element T1, the element T1 may break down. The large current that flows during this breakdown is undesirable because the large current causes destruction of the element T1 and the electric circuits connected thereto. Destruction of the element T1 can be suppressed by accelerating the timing at which the element T2 turns on compared to the timing at which the element T1 is destroyed. That is, the element T2 can be used as a protection element that protects the element T1.

VBG in the element T1 and VISO in the element T2 may be made common (broken line in the figure) or may be adjusted individually. This is easily realized by wiring connection. In addition, as will be described later, it is also possible to realize a structure in which either VBG or VISO in FIG. 1 automatically becomes GND.

Here, the region on the plane in the semiconductor layer where electric field strength becomes high during the off state on the element T1 side is the region between the gate (G) and the drain (D) where the potential difference at both ends becomes particularly large, and the region where electric field strength becomes high during the off state on the element T2 side is the region between the collector (C) and the base (B). Therefore, in order to realize a high breakdown voltage, it is necessary to make each of these regions wide along the electric field direction. In FIG. 1, the drain (D) of the element T1 and the collector (C) of the element T2 are made common (potential VD), and in addition, in this semiconductor device 1, these regions (breakdown voltage securing region J which will be described later) are formed to overlap and serve both functions in plan view. Therefore, the entire semiconductor device 1 can be miniaturized even in the case of setting the breakdown voltage of the element T1 and the element T2 high.

FIG. 2 is a cross-sectional view showing the structure of this semiconductor device 1. Here, a cross section of the portion where the element T1 and the element T2 in FIG. 1 are formed is shown, and these are formed on a p-type substrate (semiconductor substrate) 10 that is p-type (first conductivity type). Here, the ranges of the region functioning as the aforementioned element T1 (switching element region R1), the region functioning as the element T2 (protection element region R2), and the breakdown voltage securing region J are also shown above. In this structure, the case where there is no broken line in FIG. 1 (the case where VBG in the element T1 and VISO in the element T2 are independently controlled) is illustrated.

In the figure, the n layer (first semiconductor region) 11 that is low concentration n-type (second conductivity type) is widely formed in the illustrated shape on the surface of the p-type substrate 10, and both the element T1 and the element T2 in FIG. 1 are formed using this n layer 11. In FIG. 2, the right side of the n layer 11 is the low potential side (side close to ground potential), and the left side is the high potential (for example, +1000V or higher) side. The depth of the n layer 11 is not uniform, and the n layer 11 is formed deep on the high potential side and the low potential side, and formed shallow at a constant depth in the middle. The structure in which the n layer 11 is deep on the high potential side and extended shallow at a constant depth on the lower potential side than this is effective for increasing the breakdown voltage of the n layer 11. However, such a depth directional profile on the high potential side is set as appropriate.

On the surface of the left side (high potential side) of the n layer 11 in the figure, an n⁺ layer (common contact region) 12 which is a high concentration n-type layer is formed. The n⁺ layer 12 functions as a contact layer in the drain (D) region of T1 and the collector (C) region of T2 in FIG. 1, and the potential thereof is set to VD in FIG. 1. On the other hand, on the surface of the right side (low potential side) of the n layer 11 in the figure, low concentration p layer (second semiconductor region) 13 and p layer (third semiconductor region) 14 are formed to be separated from each other, with the p layer 13 being used in the element T1 and provided on the right side in the figure, and the p layer 14 being used in the element T2 and provided on the left side in the figure, respectively. On the surface of the p layer 13, an n⁺ layer (fourth semiconductor region) 15 that is high concentration n-type and a p⁺ layer 16 that is high concentration p-type are locally formed on the left and right in the figure. On the other hand, on the surface of the p layer 14, an n⁺ layer (fifth semiconductor region) 17 and a p⁺ layer 18 are locally formed on the left and right in the figure similarly.

The p layer 13 functions as a body layer of the element T1 (MOSFET), and the potential of the p layer 13 is set to VBG in FIG. 1. The n⁺ layer 15 functions as a source(S) region of the element T1, and the potential of the n⁺ layer 15 is set to VS in FIG. 1. The p⁺ layer 16 is formed for contact to the p layer 13 that serves as the body layer, and the potential of the p⁺ layer 16 is set to VBG. On the other hand, the player 14 functions as a base (B) region of the element T2, and the n⁺ layer 17 functions as an emitter (E) region of T2. The p⁺ layer 18 is formed for contact to the p layer 14 that serves as the base, and the potentials of the p⁺ layer 18 and the n⁺ layer 17 are set to VISO in FIG. 1.

An interlayer insulating layer 20 composed of a silicon oxide film is formed on the semiconductor substrate 10 in which this structure is formed, and each wiring is connected to each of the above layers through openings formed in the interlayer insulating layer 20, thereby realizing the circuit configuration of FIG. 1. First, a drain electrode (common electrode) 21 of the element T1 is connected to the n⁺ layer 12. As described above, the drain electrode 21 whose potential is set to VD in the figure also serves as the collector electrode of the element T2. A source electrode (second main electrode) 22 whose potential is set to VS is connected to the n⁺ layer 15, and on the right side thereof in the figure, a back gate electrode (second control electrode) 23 whose potential is set to VBG is connected to the p⁺ layer 16. As described above, in this semiconductor device 1, VS, VBG, and VISO in FIG. 1 are controlled independently. In addition, generally, the potential of the p-type substrate 10 is set to GND.

In addition, a gate electrode (first control electrode) 25 whose potential is set to VG in FIG. 1 is formed to face the surface of the p layer 13 from the n⁺ layer 15 to the location where the n layer 11 is exposed on the left side surface thereof, through a gate oxide film 24 that is thinner than the interlayer insulating layer 20. With this structure, the element T1 which is a MOSFET that operates using the drain electrode 21, the source electrode 22, the gate electrode 25 (and further the back gate electrode 23) is formed. In this MOSFET, in the case where an on current flows through the n layer 11 from the p layer 13 to the n⁺ layer 12 during the on state, and a high voltage is applied to the drain electrode 21 during the off state, at least a part of the n layer 11 in this region is depleted.

On the other hand, an emitter electrode (protection element side second electrode) 26 whose potential is set to VISO in FIG. 1 is connected to the n⁺ layer 17 and the p⁺ layer 18. Thereby, the element T2 in FIG. 1 is formed. In the normal off state of the element T1, VISO is set to a potential close to ground potential also in the element T2, and at least a part of the n layer 11 that functions as a part of the element T2 becomes depleted. Therefore, the influence that the element T2 exerts on the operation of the aforementioned element T1 is small.

Also, in FIG. 2, the n layer 11 between the p layer 14 and the n⁺ layer 12 on the surface side becomes a region (breakdown voltage securing region) J where the breakdown voltage should be secured because electric field strength in the depletion layer formed during the off state of the element T1 increases. Here, in order to secure the breakdown voltage, multiple field plates 30 are arranged along the left-right direction in the figure (direction in which an electric field distribution is generated during use) on the surface between the n⁺ layer 17 and the n⁺ layer 12, through a silicon oxide film thicker than the aforementioned gate oxide film 24. Among these, the field plate 30 on the highest potential side (left side in the figure) is connected to the drain electrode 21, and the field plate 30 on the lowest potential side (right side in the figure) is connected to the emitter electrode 26, respectively. The potential between the n⁺ layer 17 (potential VISO) and the n⁺ layer 12 (potential VD) is distributed by mutual capacitive coupling to adjacent field plates 30 between these, whereby the surface potential of the n layer 11 in the region J where the field plates 30 are arranged is appropriately distributed, and a local increase in electric field strength is suppressed. The action of such field plates 30 is as described in, for example, Japanese Patent No. 3275964. That is, this structure can increase the breakdown voltage in the breakdown voltage securing region J.

In FIG. 2, the leftmost field plate 30 is connected to the drain electrode 21, and the rightmost field plate 30 is connected to the emitter electrode 26, respectively through via wirings formed in the interlayer insulating layer 20, whereby the potentials of the field plates 30 on both end sides are determined as described above. However, for example, without providing such via wirings, the leftmost field plate and the drain electrode may be provided in close proximity in the horizontal or vertical direction in the figure and capacitively coupled in the same manner as between other field plates. The same applies to the relationship between the rightmost field plate 30 and the emitter electrode 26. That is, as long as similar effects can be obtained using the arrangement of field plates, the positional (connection, coupling) relationship between the field plates at the left and right (high potential side, low potential side) end portions and the drain electrode (high potential side electrode) and emitter electrode (low potential side electrode) can be appropriately set.

Since the thick silicon oxide film in the region J where the field plates 30 are actually formed is formed as a LOCOS oxide film, the surface of the semiconductor layer (n layer 11 etc.) in this region is actually positioned below the surface of the p layer 13, etc. directly below the gate electrode 35, and these surfaces are not on the same plane. In FIG. 2, the surfaces of the semiconductor layers are described in a simplified manner as constituting the same plane. The same applies to the cross-sectional views described hereinafter.

Also, as described above, the gate electrode 25 is formed on the p layer 13, but the gate electrode 25 further extends toward the p layer 14 side in FIG. 2, and in this portion, faces the surface of the n layer 11 through a thick silicon oxide film similar to the field plate 30 described above. In the normal off state of the element T1, depletion layers expand from the interface between the p layer 14 and the n layer 11, but in the case where VBG in the element T1 and VISO in the element T2 are controlled independently, the potentials of the p layer 13 and the player 14 differ from the potential of the n layer 11. As a result, the depletion layer expanding from the p layer 13 side and the depletion layer expanding from the player 14 side in the n layer 11 may come into contact with each other (punch through). By providing a portion (inter-element field plate 251) that faces the surface of such n layer 11 and controls the surface potential thereof in the same manner as the field plate 30 as a part of the gate electrode 25 (or an extension portion of the gate electrode 25) between the p layer 13 and the p layer 14, punch through is less likely to occur. An inter-element field plate that is separate from the gate electrode may be provided.

In the structure of FIG. 2, in the case where a high voltage is applied to the drain electrode 21 during the off state of the element T1, the n layer 11 is depleted. In the case of gradually increasing the voltage of the drain electrode 21, breakdown may occur in this depletion layer. The large current that flows during this breakdown causes destruction of the element T1 and the electric circuits connected thereto, which is undesirable. By accelerating the timing at which the element T2 turns on compared to the timing at which the element T1 is destroyed in this manner, destruction of the element T1 can be suppressed. In other words, the element T2 can be used as a protection element that protects the element T1. At this time, making the on voltage of the element T2 lower than the breakdown voltage of the element T1 can be easily realized by, for example, adjusting the impurity concentration of the p layer 14.

In addition, during the on state of normal operation of the element T1, the lower side of the p layer 14 in FIG. 2 becomes a path through which the on current of the element T1 flows. Therefore, in order to sufficiently secure the thickness of the n layer 11 on the lower side of the p layer 14, it is preferable that the n layer 11 on the lower side of the p layer 14 be formed deeply, as illustrated. As described above, the n layer 11 is formed shallowly at a constant depth in the breakdown voltage securing region J, but directly below the p layer 14 and the p layer 13, the n⁻ layer 11 is formed deeper than directly below the breakdown voltage securing region J.

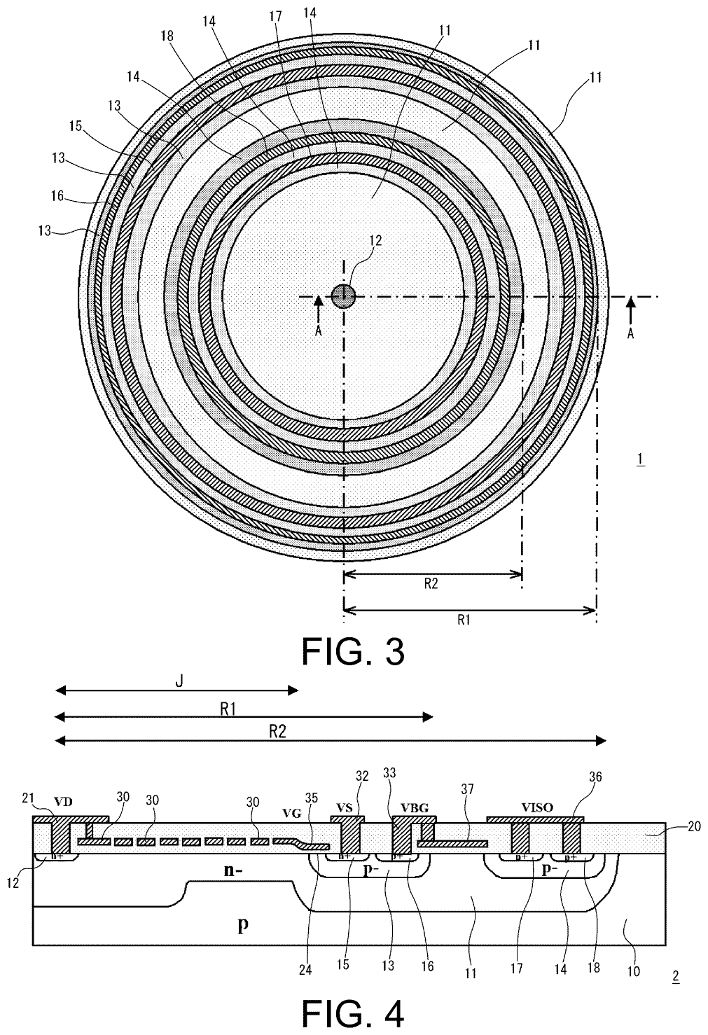

FIG. 3 is a plan view as viewed from above, showing the configuration of the semiconductor device 1 of FIG. 2. The cross section of FIG. 2 corresponds to the cross section in the A-A direction in this figure. Here, the semiconductor device 1 is made circular, centered on the n⁺ layer 12 which becomes the high potential side, and the planar shape of each layer formed on the semiconductor substrate (n⁺ layer 12, n layer 11, p layer 13 and n⁺ layer 15 and p⁺ layer 16 therein, p layer 14 and n⁺ layer 17 and p⁺ layer 18 therein) is illustrated here, and each of the above layers on the surface of the semiconductor substrate used here is formed into an annular shape. The above electrodes, etc. are connected corresponding to the layers as shown in FIG. 2. The gate electrode 25 is similarly formed in an annular shape to directly control on/off of the current path, but the other electrodes are not necessarily formed into an annular shape like the layers. In addition, for example, as long as on/off of the current path can be similarly controlled, the gate electrode may also be divided in the circumferential direction.

As shown here, the semiconductor device 1 is formed into a circular shape, with the n⁺ layer 12, which is the high potential side region, as the center and the low potential side region as the outer side in the radial direction. The element T1 which is a MOSFET is formed in the region (switching element region) R1 along the radial direction, and the element T2 which is an npn transistor is formed in the region (protection element region) R2 which is a part of the inner side thereof. Since the region R2 can be provided to overlap with the inside of the region R1, this semiconductor device 1 can be miniaturized compared to the technology described in Patent Document 1. Therefore, this semiconductor device 1 is a compact semiconductor device with a high breakdown voltage, in which the element T1 which is a switching element and the element T2 which is a protection element for protecting the element T1 are combined. An example in which the planar shape of each layer shown in FIG. 3 is changed will be described later. Moreover, the n⁺ layer serving as the common contact region and the drain electrode serving as the common electrode may have a shape in which the semiconductor layer constituting the n⁺ layer and the metal layer constituting the electrode are not actually formed at the center thereof, such as an annular shape when viewed in plan. Even in this case, these central portions are understood as the center of the circle, etc. that constitutes the outer shape.

A modification example (first modification example) of the above semiconductor device 1 will be described. The circuit configured by this semiconductor device 2 is similar to FIG. 1, but the structure on the semiconductor substrate that realizes this differs from FIG. 2. FIG. 4 is a cross-sectional view corresponding to FIG. 2, showing the structure of this semiconductor device 2.

Here, the n layer 11, the n⁺ layer 12, and the drain electrode 21 have the same structure as in FIG. 2. However, here, the positional relationship of the structure related to the above element T1 and element T2 is reversed from the structure in FIG. 2. That is, in FIG. 4, the player 13 constituting the element T1 and the n⁺ layer 15 and the p⁺ layer 16 therein are formed on the side close to the drain electrode 21 (radially inner side in FIG. 3), and the p layer 14 constituting the element T2 and the n⁺ layer 17 and the p⁺ layer 18 therein are formed on the side far from the drain electrode 21 (radially outer side in FIG. 3), and accordingly, the source electrode 32, the back gate electrode 33, and the gate electrode 35 are provided on the close side where the p layer 13 exists, and the emitter electrode 36 is provided on the far side where the p layer 14 exists.

In this case, the field plates 30 are also provided in the same manner as in FIG. 2. Here, the field plate 30 on the highest potential side is connected to the drain electrode 21 in the same manner as in FIG. 2, but for the field plate 30 on the lowest potential side, as illustrated, the gate electrode 35 is extended toward the field plate 30 side on the left side thereof, thereby creating a structure equivalent to the field plate 30 on the lowest potential side in FIG. 2.

Also, in this case, an inter-element field plate 37 is provided between the p layer 13 and the p layer 14, and the inter-element field plate 37 is connected to the back gate electrode 33. Since the potential VBG applied to the back gate electrode 33 is also close to the ground potential, when the potential of the n layer 11 in this portion is taken as a reference, the inter-element field plate 37 has a potential on the negative side, thereby obtaining the same effect as the inter-element field plate 251 in FIG. 2. In this case, in the same manner as described above, the on voltage of the element T2 can be made lower than the breakdown voltage of the element T1 by adjusting the impurity concentration of the p layer 14. The inter-element field plate 37 may be connected to the p⁺ layer 18 having a potential of VISO instead of the back gate electrode 33.

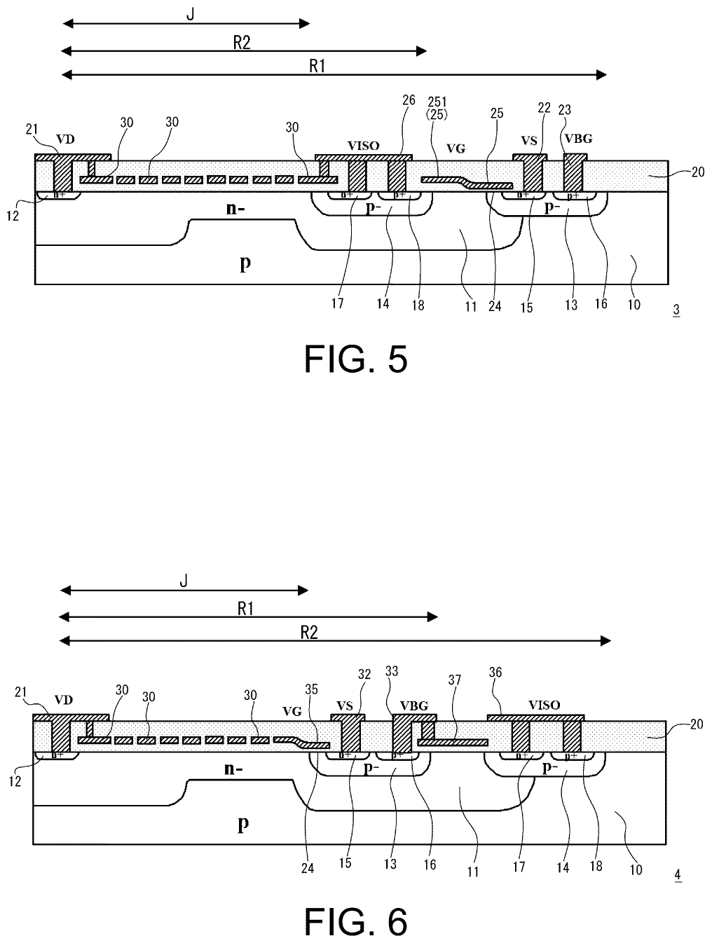

A further modification example (second modification example) of the above semiconductor device 1 will be described. FIG. 5 is a cross-sectional view corresponding to FIG. 2, showing the structure of this semiconductor device 3.

In the structure of FIG. 2, the outer p layer 13 is formed in the n layer 11, whereas in FIG. 5, the end portion on the low potential side (right side in the figure) of the n layer 11 is set on the high potential side (left side in the figure) compared to the structure of FIG. 2, so the n layer 11 is not formed outside the p layer 13, and the p layer 13 outside the n layer 11 and the p-type substrate 10 are in direct contact. Therefore, VBG in FIG. 1 becomes equal to GND, which is the potential of the p-type substrate 10. Except for this point, the structure of FIG. 5 is no different from the structure of FIG. 2.

In this case, VBG in the element T1 is set to GND. On the other hand, since it is not necessary to separate the p layer 13 and the p-type substrate 10 with the n⁻ layer 11 interposed therebetween, this semiconductor device 3 can be miniaturized compared to the aforementioned semiconductor device 1.

Similarly, FIG. 6 is a cross-sectional view showing the structure of a semiconductor device 4 (third modification example), in which the aforementioned semiconductor device 2 is modified in the same manner as the aforementioned semiconductor device 3.

In the structure of FIG. 4, the outer p layer 14 is formed in the n layer 11, whereas in FIG. 6, the end portion on the low potential side (right side in the figure) of the n layer 11 is set on the high potential side (left side in the figure) compared to the structure of FIG. 4, the n layer 11 is not formed outside the p layer 14, and the p layer 14 outside the n layer 11 and the p-type substrate 10 are in contact. Therefore, VISO in FIG. 1 becomes equal to the potential GND of the p-type substrate 10. Except for this point, the structure of FIG. 6 is no different from the structure of FIG. 4.

In this case, VISO in the element T2 is set to GND. On the other hand, since it is not necessary to separate the p layer 14 and the p-type substrate 10 through the n layer 11, this semiconductor device 4 can be miniaturized compared to the aforementioned semiconductor device 2.

The aforementioned first to third modification examples (semiconductor device 2 to semiconductor device 4) have different cross-sectional structures (FIG. 4 to FIG. 6) from the aforementioned semiconductor device 1 (FIG. 2). In contrast, the modification examples described below have different planar structures from the aforementioned semiconductor device 1 (FIG. 3).

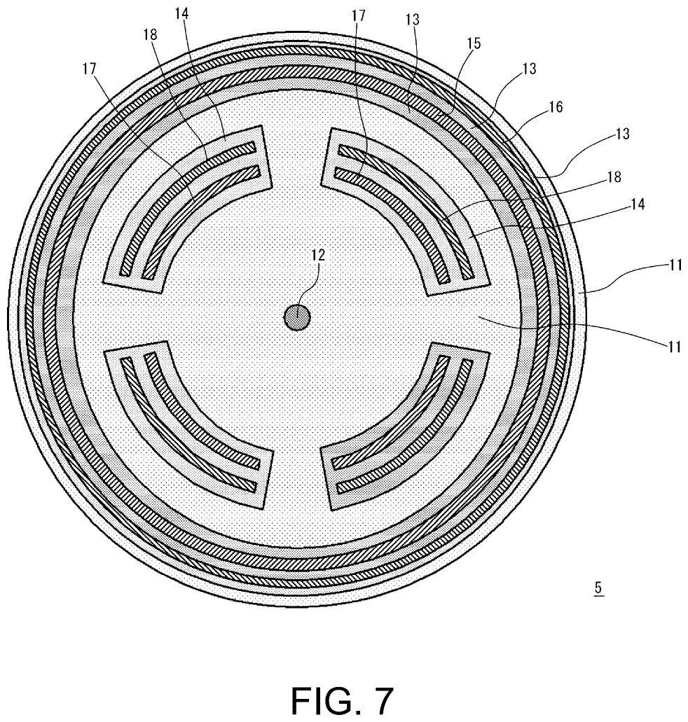

FIG. 7 is a plan view corresponding to FIG. 3, showing the structure of a semiconductor device 5 as the fourth modification example. In this semiconductor device 5, similar to the aforementioned semiconductor device 1, the element T1 (player 13, etc.) is formed on the radially outer side, and the element T2 (p layer 14, etc.) is formed on the radially inner side. In FIG. 3, the p layer 14 and the n⁺ layer 17 and the p⁺ layer 18 therein have the same annular shape as the p layer 13 and the n⁺ layer 15 and the p⁺ layer 16 therein, whereas in this semiconductor device 5, the p layer 14 constituting the element T1 and the n⁺ layer 17 and the p⁺ layer 18 therein are divided into four parts in the circumferential direction. Therefore, in the structure of FIG. 7, regions where the p layer 14 is not formed in the circumferential direction are formed at four locations: top, bottom, left, and right in FIG. 7.

In the structure of FIG. 3, the p layer 14 has an annular shape and is located inside the p layer 13, so the current flowing through the element T1 in the element region R1 needs to flow within the n layer 11 directly below the player 14. By providing regions where the p layer 14 is not formed between the regions where adjacent p layers 14 are formed in the circumferential direction as shown in FIG. 7, the on current of the element T1 can flow smoothly in these regions. That is, the on current of the element T1 formed on the radially outer side of the element T2 can be increased.

In the case of providing the inter-element field plate 251 (field plate between the p layer 13 and the p layer 14) in FIG. 2 in the structure of FIG. 7, it is preferable to extend this field plate also above the n layer 11 between adjacent p layers 14 in the circumferential direction. This suppresses the region between adjacent p layers 14 in the circumferential direction from being blocked by a depletion layer, and this region can be effectively used as a current path as described above.

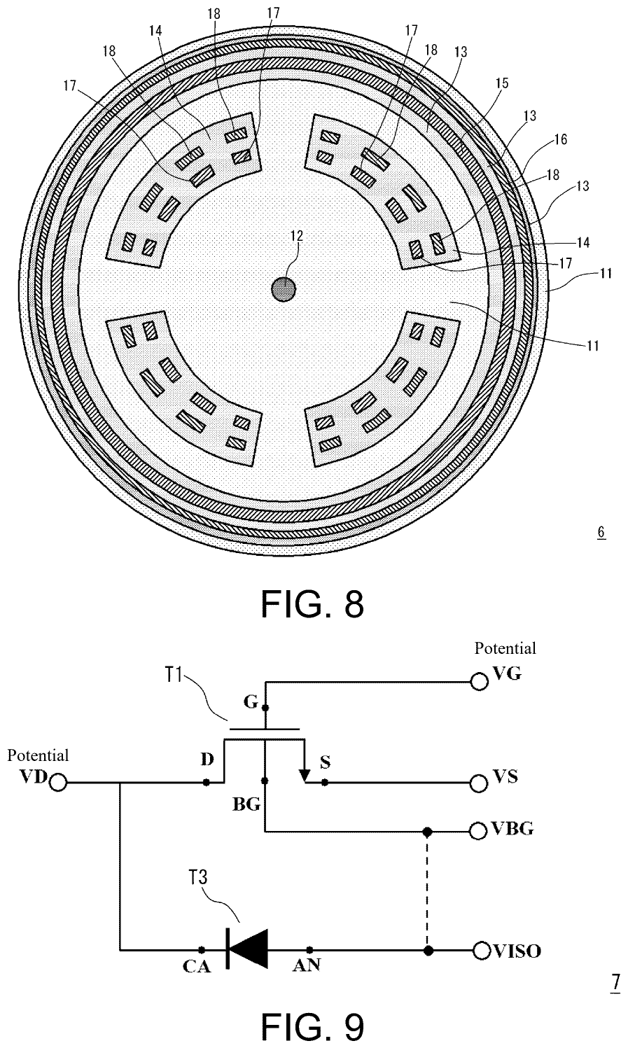

Furthermore, in a semiconductor device 6 (fifth modification example) shown in FIG. 8, the n⁺ layer 17 and the p⁺ layer 18 in the divided p layer 14 are further finely divided. This enables fine adjustment of the characteristics (on voltage, etc.) of the element T2.

In the semiconductor device 5 and the semiconductor device 6, the total area of the p layer 14 (base layer of the element T2) is smaller compared to the semiconductor device 1, etc. described above. As a result, the protection capability of the element T2 may decrease. This can be addressed by methods such as lowering the on voltage of the element T2 through adjustment of the impurity concentration of the p layer 14. On the other hand, the allowable amount of the on current of the element T1 can be increased to easily secure the current path for the on current of the element T1 as described above.

Additionally, in the circuit of FIG. 1, the element T2 which is an npn transistor is used as a protection element. However, instead of an npn transistor, a diode can also be used as the element T2 in FIG. 1. FIG. 9 is a circuit diagram corresponding to FIG. 1, showing the configuration of a semiconductor device 7 as a modification example (sixth modification example) using such an element T3 (diode) serving as a protection element. In this case, the cathode (CA) of the diode serving as the element T3 is used instead of the collector (C) in FIG. 1, and the anode (AN) is used instead of the emitter (E) in FIG. 1. In this case, during normal operation in which VD is positive, this diode is reverse-biased, so no current flows, but a current flows in response to VD exceeding the breakdown voltage of the diode, and the element T1 is protected in the same manner as in the case of using the element T2 described above. Therefore, the element T1 is protected by setting the breakdown characteristics of this diode to protect the element T1.

In this case, for example, in FIG. 2, the n layer 11 and the n⁺ layer 12 can be similarly used as the n-type layer constituting the cathode (CA), the p layer 14 and the p⁺ layer 18 can be similarly used as the p-type layer constituting the anode (AN), and the n⁺ layer 17 serving as the emitter (E) is not formed. In other words, the semiconductor device 7 of FIG. 9 can be obtained by forming the same structure as the semiconductor devices 1 to 6 except that the n⁺ layer 17 is not provided in the semiconductor layer. In this case, the setting of the breakdown voltage (breakdown characteristics) of the element T3 can be adjusted by the impurity concentration of the p layer 14, etc.

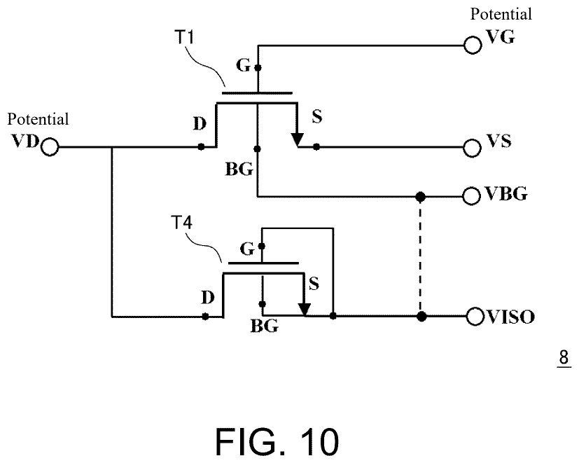

Further, as the protection element, an n-channel type MOSFET (LDMOS) similar to the element T1 can be used instead of an npn transistor. FIG. 10 shows the configuration of a semiconductor device 8 as such a modification example (seventh modification example). An element (protection element) T4 used here is a MOSFET similar to the element T1, and the source (S), gate (G), and back gate (BG) are connected as illustrated. For example, in the case of making the interlayer insulating layer 20 directly below the rightmost field plate 30 in the figure connected to the emitter electrode 26 in FIG. 2 into a thinner gate oxide film 24, this field plate 30 can serve as the gate (G) of the element T4 in FIG. 10, and this can be connected to the p⁺ layer 18 and the n⁺ layer 17 by the emitter electrode 26, to easily realize this configuration. In the element T2 of the first to third modification examples (semiconductor devices 2 to 6) described above, the protection element T4 can be similarly realized by modifying the structure in the vicinity of the field plate.

The overall shape of the above semiconductor device 1, etc. is circular, and each region such as the p layer 13 has an annular shape. However, it is clear that even if these are not circular (annular), similar effects can be achieved as long as each region is annular (for example, elliptical annular). Furthermore, it is also clear that similar effects can be achieved even in the case where these regions are not in closed annular shapes, or at least one of the n⁺ layer 15 and the n⁺ layer 17 is arranged intermittently in the circumferential direction. For example, similar effects are achieved even in the case where the structure of FIG. 2 extends uniformly perpendicular to the paper surface, and the regions are formed into parallel strip shapes. In these cases, the shapes of the field plates provided in the breakdown voltage securing region are also appropriately set accordingly. The same applies to the inter-element field plate.

However, as shown in FIG. 3, etc., the potential distribution can be made uniform in the circumferential direction by forming each layer (particularly, p layer 13 and p layer 14) into an annular shape centered on the n⁺ layer 12, and an increase in electric field strength at specific locations in the circumferential direction is suppressed, so a high breakdown voltage can be obtained.

Furthermore, although multiple field plates 30 are used in the breakdown voltage securing region in the above example, it is not necessary to provide field plates in the breakdown voltage securing region in the case where the breakdown voltage can be secured without using such field plates. Well-known resistive field plates may also be used instead of the multiple field plates 30 in the breakdown voltage securing region. In this case, the structure of the semiconductor device becomes simpler. The same applies to the inter-element field plate.

Besides, other layers can be appropriately added to or deleted from the semiconductor layer. It is also clear that a similar configuration can be applied to the above example even in the case where all p-type and n-type in the semiconductor are reversed.

What is claimed is:

1. A semiconductor device, in which a switching element whose on/off is controlled between a first main electrode on a high potential side and a second main electrode on a low potential side, and a protection element that bypasses and flows a current between a protection element side first electrode on the high potential side and a protection element side second electrode on the low potential side during an off state of the switching element are formed on a semiconductor substrate, the semiconductor device comprising:
a first semiconductor region of a second conductivity type formed on a surface side of the semiconductor substrate of a first conductivity type, wherein the second conductivity type is opposite to the first conductivity type;
a common electrode serving as both the first main electrode and the protection element side first electrode;
a common contact region of the second conductivity type formed locally with a high impurity concentration on the first semiconductor region and connected to the common electrode;
a second semiconductor region of the first conductivity type locally formed in the first semiconductor region separated from the common contact region in plan view;
a third semiconductor region of the first conductivity type separated from the common contact region and the second semiconductor region and locally formed in the first semiconductor region in plan view; and
a fourth semiconductor region of the second conductivity type locally formed in the second semiconductor region in plan view,
wherein one of the second semiconductor region and the third semiconductor region is formed to surround the other of the second semiconductor region and the third semiconductor region on an outer side as viewed from the common contact region,
the fourth semiconductor region and the second main electrode are connected, and
the third semiconductor region and the protection element side second electrode are connected.

2. The semiconductor device according to claim 1, wherein a fifth semiconductor region of the second conductivity type is provided in the third semiconductor region in plan view, and the protection element side second electrode is connected to the fifth semiconductor region and the third semiconductor region.

3. The semiconductor device according to claim 1, wherein the second semiconductor region is formed in an annular shape surrounding the common contact region in plan view.

4. The semiconductor device according to claim 1, wherein the other of the second semiconductor region and the third semiconductor region is the third semiconductor region.

5. The semiconductor device according to claim 4, wherein the third semiconductor region is divided and provided as a plurality of regions in plan view.

6. The semiconductor device according to claim 1, wherein the other of the second semiconductor region and the third semiconductor region is the third semiconductor region, and the first semiconductor region is formed deeper below the third semiconductor region than an inner side of the third semiconductor region in plan view.

7. The semiconductor device according to claim 1, comprising:
a first control electrode controlling on/off between the first main electrode and the second main electrode in the switching element, and formed on the second semiconductor region; and
a second control electrode connected to the second semiconductor region.

8. The semiconductor device according to claim 7, comprising an inter-element field plate electrically connected to any of the first control electrode, the second control electrode, and the third semiconductor region, and facing a surface of the first semiconductor region between the second semiconductor region and the third semiconductor region in plan view through an insulating layer.

9. The semiconductor device according to claim 1, wherein the one of the second semiconductor region and the third semiconductor region is the third semiconductor region.

10. The semiconductor device according to claim 3, wherein the first semiconductor region is not formed outside the one of the second semiconductor region and the third semiconductor region.
